(19) United States
(12) Patent Application Publication
(10) Pub. No.: US 2016/0181267 A1
(43) Pub. Date: Jun. 23, 2016

(54) NON-VOLATILE MEMORY CELL, NAND-TYPE NON-VOLATILE MEMORY, AND METHOD OF MANUFACTURING THE SAME

(71) Applicant: Powerchip Technology Corporation, Hsinchu (TW)

(72) Inventors: Chih-Yuan Chen, Hsinchu City (TW); Zih-Song Wang, Nantou County (TW); Hann-Ping Hwang, Hsinchu City (TW); Tzung-Hua Ying, Hsinchu City (TW); Yen-Cheng Fang, Hualien County (TW)

(21) Appl. No.: 14/656,703

(22) Filed: Mar. 12, 2015

(30) Foreign Application Priority Data
Dec. 17, 2014 (TW) 103144101

(51) Int. Cl. H01L 27/115; H01L 29/40; H01L 21/3065; H01L 29/49; H01L 21/308; H01L 21/306; H01L 29/66; H01L 29/423

(52) U.S. Cl. CPC H01L 27/11548; H01L 27/11524; H01L 27/11556; H01L 29/66825; H01L 29/66553; H01L 29/66492; H01L 29/401; H01L 29/42324; H01L 29/4925; H01L 21/3085; H01L 21/30608; H01L 21/3065

(57) ABSTRACT

A non-volatile memory cell, a NAND-type non-volatile memory, and a method of manufacturing the same are provided. The method of manufacturing the non-volatile memory cell includes the following steps. An insulating layer, a first conductive layer, an inter-gate insulating layer, a second conductive layer, and a hard mask layer are formed on a substrate in order. The hard mask layer, the second conductive layer, the inter-gate insulating layer, and the first conductive layer are patterned to form a stacked gate structure. The insulating layer on the substrate at two sides of the stacked gate structure is removed until the surface of the substrate is exposed. A portion of the substrate at two sides of the stacked gate structure is removed to form two recesses in the substrate, and each of the recesses is extended below the stacked gate structure. A source/drain region is formed in the substrate below the recesses.

### CROSS-REFERENCE TO RELATED APPLICATION

This application claims the priority benefit of Taiwan application serial no. 103144101, filed on Dec. 17, 2014. The entirety of the above-mentioned patent application is hereby incorporated by reference herein and made a part of this specification.

### BACKGROUND OF THE INVENTION

1. Field of the Invention

The invention relates to a memory and a method of manufacturing the same, and more particularly, to a non-volatile memory cell, a NAND-type non-volatile memory, and a method of manufacturing the same.

2. Description of Related Art

Among various memory products, the non-volatile memory capable of repeatedly performing actions such as storing, reading, and erasing of data and having the advantage of retaining stored data in a power failure has become a memory device widely adopted in personal computers and electronic equipment.

Moreover, the non-volatile memory array more commonly used by current industries includes a NOR-type array structure and a NAND-type array structure. Since in a NAND-type array non-volatile memory structure, each memory cell is connected in series, the density and the area utilization thereof are better than those of a NOR-type array non-volatile memory, and is widely applied in various electronic products.

However, with the rigorous development of integrated circuits, the lateral dimension of the memory is shrinking, and therefore the channel length in the memory is also reduced. Accordingly, the issue of short-channel effect occurs. Moreover, during an erase operation, oxide trap charge induced via an FN current of a floating electrode of a memory cell occurs, thus causing a fringe field distortion effect, such that device reliability is reduced.

It can therefore be known that, in the current trend of miniaturized devices, how to balance device density and device reliability in limited space is one focus of study of various industries.

### SUMMARY OF THE INVENTION

The invention provides a non-volatile memory cell, a NAND-type non-volatile memory, and a method of manufacturing the same capable of alleviating the short-channel effect and the fringe field distortion effect so as to increase device reliability.

A method of manufacturing a non-volatile memory cell of the invention includes the following steps. An insulating layer, a first conductive layer, an inter-gate insulating layer, a second conductive layer, and a hard mask layer are formed on a substrate in order. The hard mask layer, the second conductive layer, the inter-gate insulating layer, and the first conductive layer are patterned to form a stacked gate structure. The insulating layer on the substrate at two sides of the stacked gate structure is removed until the surface of the substrate is exposed. A portion of the substrate at two sides of the stacked gate structure is removed to form two recesses in the substrate, and each of the recesses is extended below the stacked gate structure. A source/drain region is formed in the substrate below the recesses.

A non-volatile memory cell of the invention includes a substrate, a stacked gate structure, an insulating layer, two recesses, and a source/drain region. The stacked gate structure is disposed on the substrate, wherein the stacked gate structure includes, from the bottom up, a first conductive layer, an inter-gate insulting layer, a second conductive layer, and a hard mask layer on the substrate. The insulating layer is disposed between the substrate and the stacked gate structure. The recesses are disposed in the substrate at two sides of the stacked gate structure, wherein each of the recesses is extended below the stacked gate structure. The source/drain region is disposed in the substrate below the recesses.

A method of manufacturing a NAND-type non-volatile memory of the invention includes the following steps. A substrate is provided, and the substrate has a select gate region. An insulating layer, a first conductive layer, and an inter-gate insulating layer are formed on the substrate in order. At least a portion of the inter-gate insulating layer in the select gate region is removed to expose a portion of the first conductive layer. A second conductive layer and a hard mask layer are formed on the substrate in order, wherein the second conductive layer covers the inter-gate insulating layer and a portion of the exposed first conductive layer. The hard mask layer, the second conductive layer, the inter-gate insulating layer, and the first conductive layer are patterned to form a plurality of stacked gate structures, and a select gate structure is formed in the select gate region at the same time. The insulating layer on the substrate at two sides of each of the stacked gate structures and the select gate structure is removed until the surface of the substrate is exposed. A portion of the substrate at two sides of each of the stacked gate structures and the select gate structure is removed to form a plurality of recesses in the substrate, and each of the recesses is extended below the stacked gate structure or the select gate structure. A source/drain region is formed in the substrate below the recesses at two sides of each of the stacked gate structures and the select gate structure.

A NAND-type non-volatile memory of the invention includes a substrate, a plurality of stacked gate structures and a select gate structure, an insulating layer, a plurality of recesses, and a plurality of source/drain regions. The substrate has a select gate region. The stacked gate structures are disposed on the substrate in series, the select gate structure is disposed on the substrate in the select gate region at two sides of the stacked gate structures, and each of the stacked gate structures includes, from the bottom up, a first conductive layer, an inter-gate insulating layer, a second conductive layer, and a hard mask layer on the substrate. The insulating layer is disposed between each of the stacked gate structures and the substrate and disposed between the select gate structure and the substrate. The recesses are disposed in the substrate at two sides of the stacked gate structures and the select gate structure, and each of the recesses is extended below the stacked gate structure or the select gate structure. The source/drain regions are disposed in the substrate below the recesses at two sides of the stacked gate structures and the select gate structure.

In an embodiment of the invention, the method of removing a portion of the substrate includes at least one of a wet etching process and a dry etching process.

In an embodiment of the invention, the method of removing a portion of the substrate includes wet dip etching.

In an embodiment of the invention, the method of Ruining the source/drain regions includes foaming a lightly-doped region in the substrate below each of the recesses.

An embodiment of the invention further includes, before the recesses are formed, forming an oxide layer on sidewalls of the stacked gate structures.

An embodiment of the invention further includes an oxide layer disposed on the sidewalls of the stacked gate structures.

In an embodiment of the invention, the source/drain regions include a lightly-doped region.

In an embodiment of the invention, the material of the first conductive layer includes doped polysilicon.

In an embodiment of the invention, the material of the second conductive layer includes doped polysilicon.

Based on the above, in the invention, recesses are formed in the substrate at two sides of the gate structures, such that the recesses are extended below the gate structures, and source/drain regions are formed in the substrate below the recesses. As a result, the short-channel effect and the fringe field distortion effect can be alleviated to increase device reliability.

Several exemplary embodiments accompanied with figures are described in detail below to further describe the disclosure in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematics of the manufacturing process of a non-volatile memory illustrated according to an embodiment of the invention.

### DESCRIPTION OF THE EMBODIMENTS

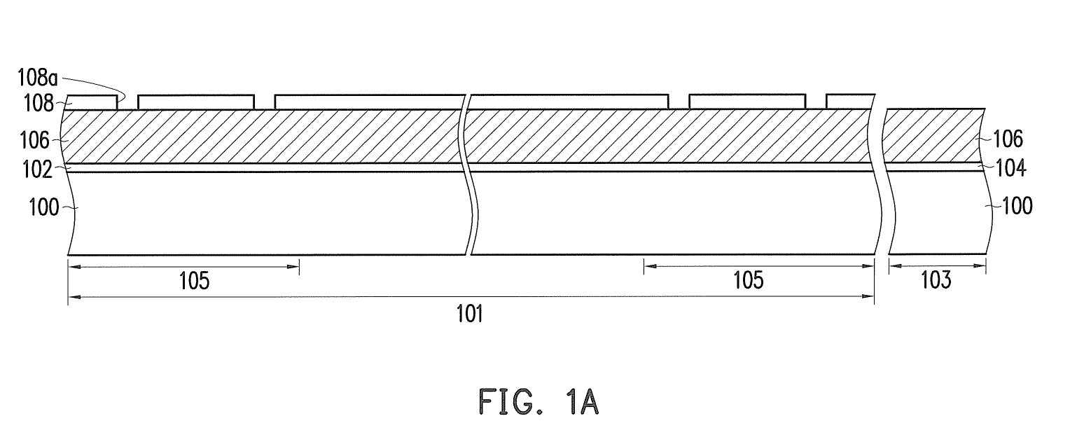

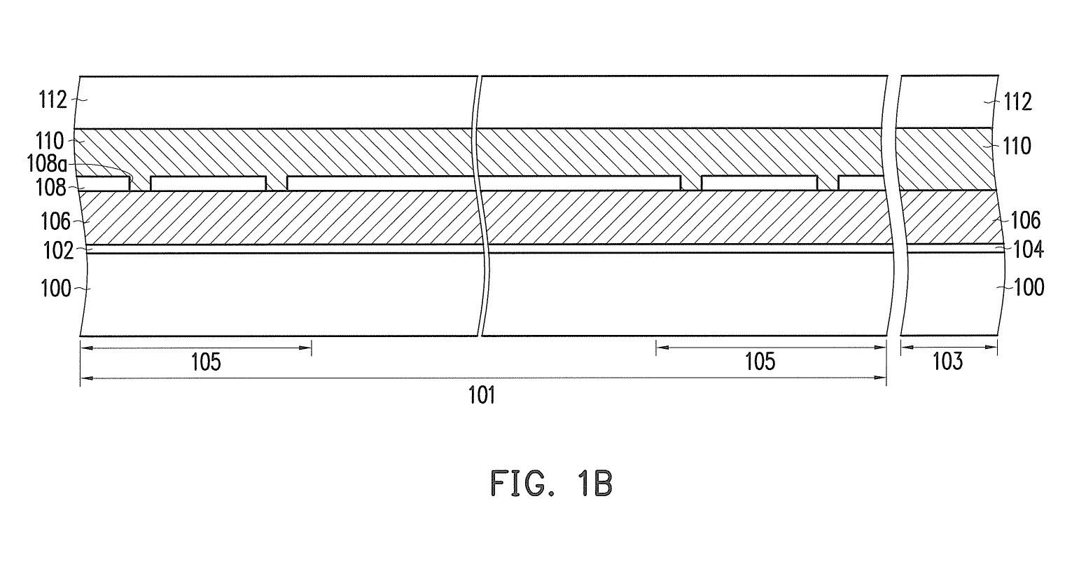

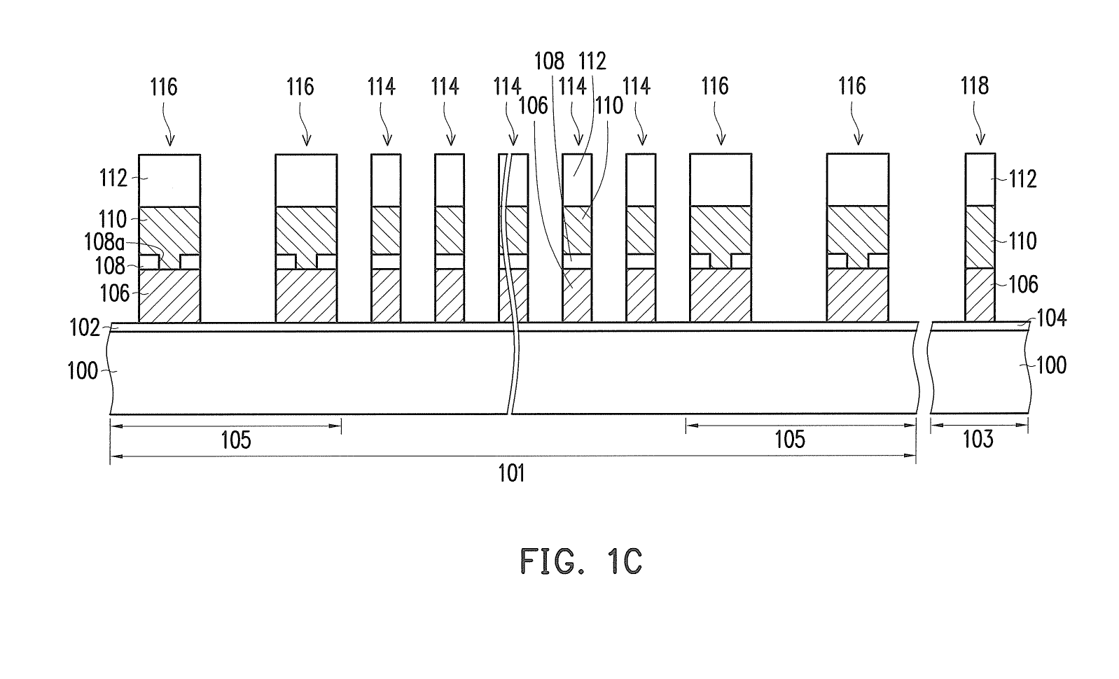

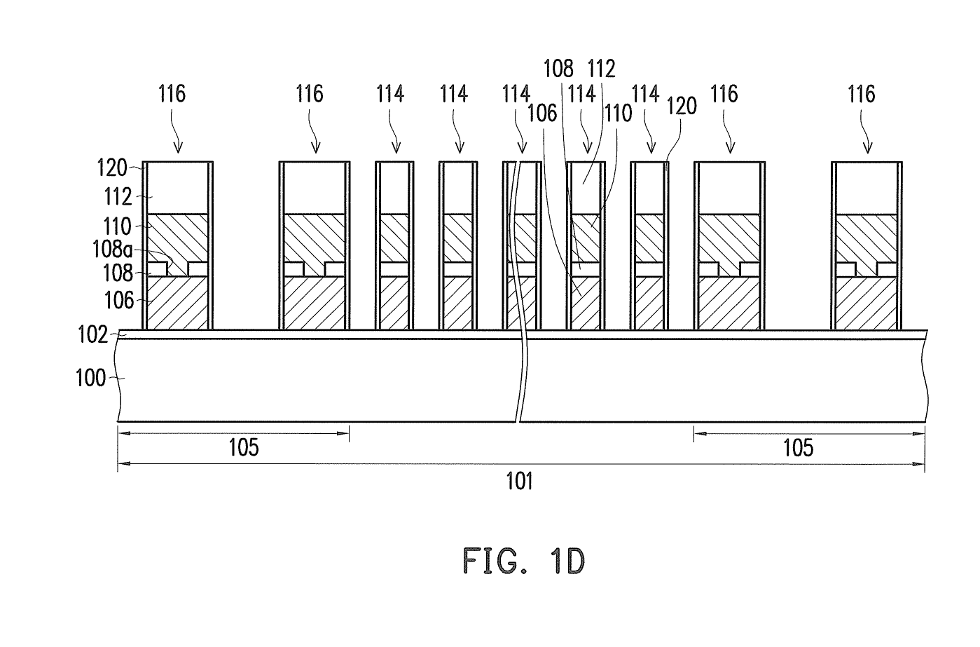

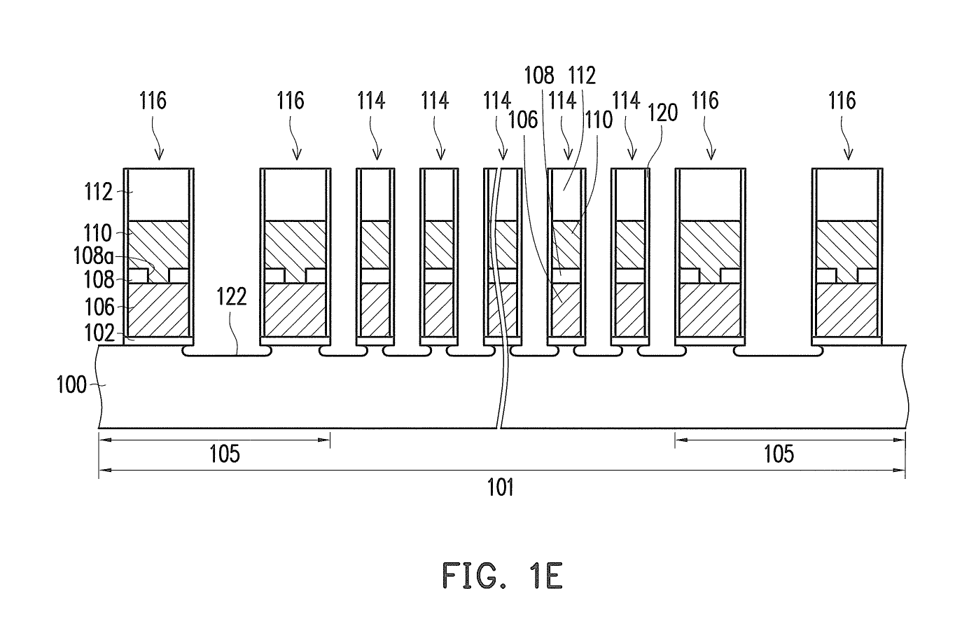

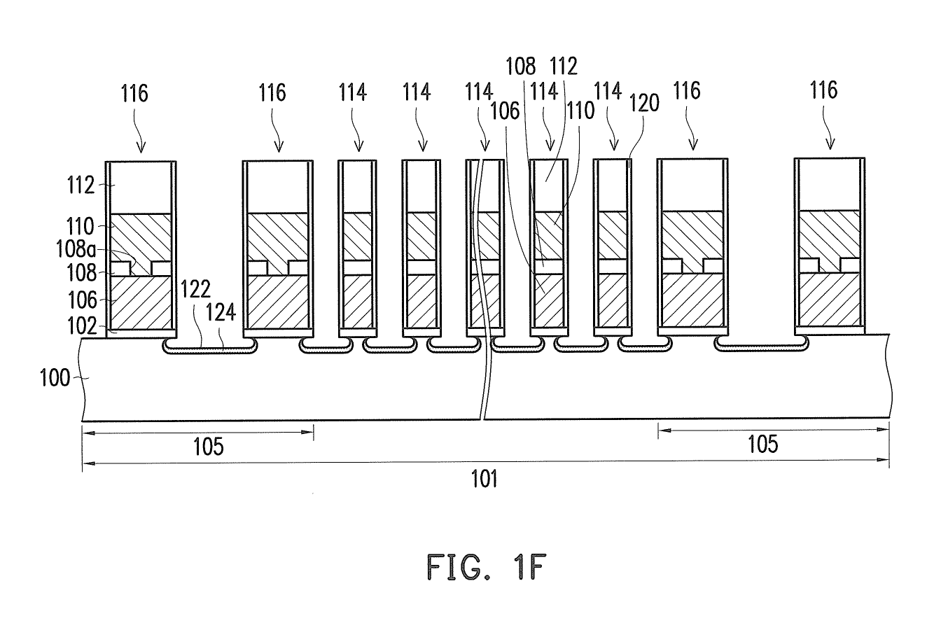

FIG. 1A to FIG. 1F are schematics of the manufacturing process of a non-volatile memory illustrated according to an embodiment of the invention. The manufacturing process of a non-volatile memory contains a non-volatile memory cell and a method of manufacturing a NAND-type non-volatile memory of the invention. First, referring to FIG. 1A, a substrate 100 is provided. The substrate 100 is, for instance, a silicon substrate or other suitable semiconductor substrates. The substrate 100 has a memory cell region 101 and a peripheral circuit region 103, and the memory cell region 101 has a select gate region 105.

Then, an insulating layer is formed on the substrate 100 in the memory cell region 101 as a tunneling dielectric layer 102, and a gate dielectric layer 104 is formed on the substrate 100 in the peripheral circuit region 103. The material of each of the tunneling dielectric layer 102 and the gate dielectric layer 104 is, for instance, silicon oxide, and the forming method of each of the two is known to those having ordinary skill in the art and is not repeated herein. Moreover, the thickness of the tunneling dielectric layer 102 and the thickness of the gate dielectric layer 104 can be the same or different.

Then, a first conductive layer 106 is formed on the substrate 100. The material of the first conductive layer 106 is, for instance, doped polysilicon. The method of forming the first conductive layer 106 includes, for instance, first performing a chemical vapor deposition process to form an undoped polysilicon layer, and then performing an ion implantation process. Alternatively, an in-situ doping method can also be used to perform a chemical vapor deposition process.

Then, an inter-gate insulating layer is formed on the substrate 100 in the memory cell region 101 as an intergate dielectric layer 108. The material of the inter-gate insulating layer 108 is, for instance, silicon oxide/silicon nitride/silicon oxide. The method of forming the inter-gate insulating layer 108 includes, for instance, first forming a first silicon oxide layer on the first conductive layer 106 via a thermal oxidation method, then performing a chemical vapor deposition process to form a silicon nitride layer on the silicon oxide layer, and then forming a second silicon oxide layer on the silicon nitride layer. Of course, the material of the inter-gate insulating layer 108 can also be silicon oxide, silicon oxide/silicon nitride, or other dielectric materials. In the present embodiment, the inter-gate insulating layer 108 in the select gate region 105 includes, for instance, an opening 108a, and the opening 108a exposes the first conductive layer 106.

The method of forming the intergate dielectric layer 108 includes, for instance, forming an insulating material layer on the substrate 100, and then forming a patterned mask layer on the substrate 100 in the memory cell region 101. The patterned mask layer (not shown) is, for instance, a patterned photoresist layer exposing at least a portion of an insulating material layer in the select gate region 105 and the insulating material layer in the peripheral circuit region 103 in the memory cell region 101. Then, an etching process is performed by using the patterned mask layer as a mask, and the exposed insulating material layer is removed to form the inter-gate insulating layer 108 having the opening 108a. Then, the patterned mask layer is removed. The method of removing the patterned mask layer includes, for instance, first ashing the patterned mask layer via oxygen plasma, and then performing a wet washing process. It should be mentioned that, in the present embodiment, the inter-gate insulating layer 108 has the opening 108a, but the invention is not limited thereto.

Then, referring to FIG. 1B, a second conductive layer 110 is formed on the substrate 100, and the second conductive layer 110 covers the inter-gate insulating layer 108 and a portion of the exposed first conductive layer 106. In other words, the second conductive layer 110 is filled in the opening 108a. Similarly, the material and the forming method of the second conductive layer 110 are, for instance, the same as those of the first conductive layer 106, but are not limited thereto. Next, a hard mask layer 112 is formed on the substrate 100. The material of the hard mask layer 112 is, for instance, silicon oxide, and is, for instance, formed by performing a chemical vapor deposition method by using tetraethyl orthosilicate (TEOS) as the reaction gas.

In an embodiment (not shown), a metal silicide layer or a metal layer can also be optionally formed on the second conductive layer 110 to reduce the resistance of the device. The material of the metal silicide layer is, for instance, tungsten silicide, titanium silicide, cobalt silicide, tantalum silicide, nickel silicide, platinum silicide, or palladium silicide; the material of the metal layer is, for instance, tungsten or titanium nitride. The method of forming the metal silicide layer or the metal layer includes, for instance, a chemical vapor deposition process or a physical vapor deposition process.

Then, referring to FIG. 1C, a patterning process is performed to pattern the hard mask layer 112, the second conductive layer 110, the inter-gate insulating layer 108, and the first conductive layer 106 in the memory cell region 101 to form a plurality of stacked gate structures 114 and a plurality of select gate structures 116 on the substrate 100 in the select gate region 105. The patterning process includes, for instance, forming a photoresist layer on the hard mask layer 112, and then performing patterning on the hard mask layer 112, the second conductive layer 110, the inter-gate insulating layer 108, and the first conductive layer 106 by using the photoresist layer as a mask. The stacked gate structures 114 are formed by, from the bottom up, the first conductive layer 106, the inter-gate insulating layer 108, the second conductive layer 110, and the hard mask layer 112 on the substrate 100. In particular, the first conductive layer 106 is used as a floating gate, and the second conductive layer 110 is used as a control gate. In an embodiment, the second conductive layer 110 and the metal silicide layer can also form the control gate together. Moreover, the select gate structures 116 located in the select gate region 105 are used as select gates. In the above, the stacked gate structures 114 and the tunneling dielectric layer 102, and the select gate structures 116 and the tunneling dielectric layer 102 form the memory cells of the non-volatile memory.

Moreover, when the patterning process is performed, the hard mask layer 112, the second conductive layer 110, and the first conductive layer 106 in the peripheral circuit region 103 are also patterned at the same time to form a stacked gate structure 118. The stacked gate structure 118 and the gate dielectric layer 104 form the transistor in the peripheral circuit region of the non-volatile memory. It should be mentioned that, although specific numbers of the stacked gate structures 114 and 118 and the select gate structures 116 are respectively illustrated in FIG. 1C, the invention is not limited thereto.

It should be mentioned that, in the present embodiment, the select gate structures 116 illustrated in FIG. 1C are exemplary, and are not intended to limit the invention. In other embodiments, the select gate structures can also have different dispositions and forming methods. For instance, in the step of FIG. 1A, all of the inter-gate insulating layers 108 in the select gate region 105 can be removed, and the resulting select gate structures do not include an inter-gate insulating layer.

Then, referring further to FIG. 1D to FIG. 1F, in all of these figures, only the memory cell region 101 is described, and the peripheral circuit region 103 is not shown.

Next, referring to FIG. 1D, after the stacked gate structures 114 and the select gate structures 116 are formed, an oxide layer 120 is formed on sidewalls of the stacked gate structures 114. The material of the oxide layer 120 is, for instance, silicon oxide, and the forming method thereof includes, for instance, performing a re-oxidation process. The function of the oxide layer 120 is to protect the stacked gate structures 114 from damage in a subsequent process. In the present embodiment, the oxide layer 120 is also formed on the sidewalls of the select gate structures 116, but is not limited thereto.

Then, referring to FIG. 1E, the tunneling dielectric layer 102 at two sides of the stacked gate structures 114 and the select gate structures 116 is removed until the surface of the substrate 100 is exposed. The method of removing the tunneling dielectric layer 102 includes, for instance, performing an etch-back process. Here, a patterned mask layer (not shown) can be used to cover the peripheral circuit region 103 such that the film layer is not damaged.

Then, a portion of the substrate 100 at two sides of the stacked gate structures 114 and the select gate structures 116 is removed to form recesses 122 in the substrate 100, and the recesses 122 are extended below the stacked gate structures 114 or the select gate structures 116. The method of removing a portion of the substrate 100 includes, for instance, at least one of a wet etching process and a dry etching process. In an embodiment, the method of forming the recesses 122 includes, for instance, removing a portion of the substrate 100 located between the stacked gate structures 114 and the two adjacent select gate structures 116 and by using the stacked gate structures 114 and the select gate structures 116 as a mask. Specifically, a portion of the substrate 100 between two adjacent oxide layers 120 is removed to form a recess having a certain depth, wherein a sidewall of the recess is substantially level with the outer wall of the oxide layers 120. The method of removing a portion of the substrate 100 includes, for instance, a dry etching process. Then, a wet etching process is performed such that a sidewall of the recess is extended outward below the stacked gate structures 114 and the select gate structures 116 to form recesses 122. Although in the present embodiment, two etching processes are performed, the invention is not limited thereto. In an embodiment, the recesses 122 can also be formed via a single process such as wet dip etching.

Next, referring to FIG. 1F, source/drain regions 124 is formed in the substrate 100 below the recesses 122 at two sides of the stacked gate structures 114 and the select gate structures 116. The method of forming the source/drain regions 124 includes forming a lightly-doped region in the substrate 100 below each of the recesses 122 via an ion implantation process.

Then, known processing steps are performed based on device requirements, and since the steps are known in the art, the steps are not repeated herein.

It should be mentioned that, in the present embodiment, before the doped region used as the source/drain region is formed in the memory device, the recesses 122 extending below the stacked gate structures 114 or the select gate structures 116 are formed. Therefore, the memory device can have a recess-type source/drain junction (S/D junction) capable of alleviating the short-channel effect and the fringe field distortion effect so as to increase device reliability.

Then, the non-volatile memory cell and the NAND-type non-volatile memory of the invention are described with reference to FIG. 1F. In the following, possible repeating content related to, for instance, the material of each component of the devices is omitted.

Referring again to FIG. 1F, the device structure of the invention includes a substrate 100, a plurality of stacked gate structures 114, a plurality of select gate structures 116, a plurality of oxide layers 120, a plurality of insulating layers 102, a plurality of recesses 122, and a plurality of source/drain regions 124. In particular, the substrate 100 has a select gate region 105. Moreover, the plurality of stacked gate structures 114 are disposed on the substrate 100 in series, and the select gate structures 116 are disposed on the substrate 100 in the select gate region 105 at two sides of the stacked gate structures 114. Each of the stacked gate structures 114 is formed by, from the bottom up, a first conductive layer 106, an inter-gate insulating layer 108, a second conductive layer 110, and a hard mask layer 112 on the substrate 100. The recesses 122 are disposed in the substrate 100 at two sides of the stacked gate structures 114, wherein each of the recesses 122 is extended below the stacked gate structure 114. In the present embodiment, the recesses 122 are further disposed in the substrate 100 at two sides of the select gate structures 116, wherein each of the recesses 122 is extended below the select gate structure 116. The source/drain regions 124 are disposed in the substrate 100 below the recesses 122. In other words, in the present embodiment, the recesses 122 are disposed between the stacked gate structures 114, between the select gate structures 116, and between the stacked gate structures 114 and the select gate structures 116.

The oxide layers 120 of the present embodiment are disposed on the sidewalls of the stacked gate structures 114 and the select gate structures 116. The insulating layers 102 are disposed between the stacked gate structures 144, the substrate 100, and the oxide layers 120, and disposed between the select gate structures 116 and the substrate 100.

Based on the above, in the invention, the recesses are formed in the substrate at two sides of the gate structures, such that the recesses are extended below the gate structures. Then, doped regions can be formed in the substrate below the recesses via a method such as ion implantation as the source/drain regions. In other words, recesses extended below the gate structures are formed between the stacked gate structures, between the select gate structures, and between the stacked gate structures and the select gate structures, and source/drain regions are formed in the substrate below the recesses. In this way, at least a portion of the source/drain regions is located below the gate structures. In particular, using shallow trenches as the source/drain regions can alleviate the short-channel effect. Moreover, the recesses extended below the gate structures can reduce the fringe field at the edge of the floating gates, and therefore electrons can be prevented from being captured at the edges of the floating gates during an erase operation, so as to reduce the fringe field distortion effect. Therefore, the method and the memory device of the invention reach the object of balancing device density and increasing device reliability.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A method of manufacturing a non-volatile memory cell, comprising:
forming an insulating layer, a first conductive layer, an inter-gate insulating layer, a second conductive layer, and a hard mask layer on a substrate in order;
patterning the hard mask layer, the second conductive layer, the inter-gate insulating layer, and the first conductive layer to form a stacked gate structure;
removing the insulating layer on the substrate at two sides of the stacked gate structure until a surface of the substrate is exposed;
removing a portion of the substrate at two sides of the stacked gate structure to form two recesses in the substrate, wherein each of the recesses is extended below the stacked gate structure; and
forming a source/drain region in the substrate below the recesses.

2. The method of claim 1, wherein a method of removing a portion of the substrate comprises at least one of a wet etching process and a dry etching process.

3. The method of claim 1, wherein a method of removing a portion of the substrate comprises wet dip etching.

4. The method of claim 1, wherein a method of forming the source/drain region comprises forming a lightly-doped region in the substrate below each of the recesses.

5. The method of claim 1, further comprising, before the recesses are formed, forming an oxide layer on a sidewall of the stacked gate structure.

6. A non-volatile memory cell, comprising:
a substrate;
a stacked gate structure disposed on the substrate, wherein the stacked gate structure comprises, from the bottom up, a first conductive layer, a gate insulting layer, a second conductive layer, and a hard mask layer disposed on the substrate;
an insulating layer disposed between the substrate and the stacked gate structure;
two recesses disposed in the substrate at two sides of the stacked gate structure, wherein each of the recesses is extended below the stacked gate structure; and
a source/drain region disposed in the substrate below the recesses.

7. The non-volatile memory cell of claim 6, further comprising an oxide layer disposed on a sidewall of the stacked gate structure.

8. The non-volatile memory cell of claim 6, wherein the source/drain region comprises a lightly-doped region.

9. The non-volatile memory cell of claim 6, wherein a material of the first conductive layer comprises doped polysilicon.

10. The non-volatile memory cell of claim 6, wherein a material of the second conductive layer comprises doped polysilicon.

11. A method of manufacturing a NAND-type non-volatile memory, comprising:
providing a substrate, the substrate having a select gate region;
forming an insulating layer, a first conductive layer, and an inter-gate insulating layer on the substrate in order;
removing at least a portion of the inter-gate insulating layer in the select gate region to expose a portion of the first conductive layer;
forming a second conductive layer and a hard mask layer on the substrate in order, wherein the second conductive layer covers the inter-gate insulating layer and a portion of the exposed first conductive layer;
patterning the hard mask layer, the second conductive layer, the inter-gate insulating layer, and the first conductive layer to form a plurality of stacked gate structures, and forming a select gate structure in the select gate region at the same time;
removing the insulating layer on the substrate at two sides of each of the stacked gate structures and the select gate structure until a surface of the substrate is exposed;
removing a portion of the substrate at two sides of each of the stacked gate structures and the select gate structure to form a plurality of recesses in the substrate, wherein each of the recesses is extended below the stacked gate structure or the select gate structure; and
forming a source/drain region in the substrate below the recesses at two sides of each of the stacked gate structures and the select gate structure.

12. The method of claim 11, wherein a method of removing a portion of the substrate comprises at least one of a wet etching process and a dry etching process.

13. The method of claim 11, wherein a method of removing a portion of the substrate comprises wet dip etching.

14. The method of claim 11, wherein a method of forming the source/drain region comprises forming a lightly-doped region in the substrate below each of the recesses.

15. The method of claim 11, further comprising, after the select gate structure is formed and before a portion of the insulating layer and a portion of the substrate are removed, forming an oxide layer on a sidewall of each of the stacked gate structures.

16. A NAND-type non-volatile memory, comprising:
a substrate, having a select gate region;
a plurality of stacked gate structures and a select gate structure, wherein the stacked gate structures are disposed on the substrate in series, the select gate structure is disposed on the substrate in the select gate region at two sides of the stacked gate structures, and each of the stacked gate structures comprises, from the bottom up, a first conductive layer, an inter-gate insulating layer, a second conductive layer, and a hard mask layer on the substrate;
an insulating layer disposed between each of the stacked gate structures and the substrate and disposed between the select gate structure and the substrate;
a plurality of recesses disposed in the substrate at two sides of the stacked gate structures and the select gate structure, wherein each of the recesses is extended below the stacked gate structure or the select gate structure; and
a plurality of source/drain regions disposed in the substrate below the recesses at two sides of the stacked gate structures and the select gate structure.

17. The NAND-type non-volatile memory of claim 16, further comprising an oxide layer disposed on sidewalls of each of the stacked gate structures.

18. The NAND-type non-volatile memory of claim 16, wherein a material of the first conductive layer comprises doped polysilicon.

19. The NAND-type non-volatile memory of claim 16, wherein a material of the second conductive layer comprises doped polysilicon.
